(19) United States
(12) Patent Application Publication
(10) Pub. No.: US 2026/0360596 A1
(43) Pub. Date: Nov. 12, 2026

(54) Trimmable Resistor Network and Reference Current Generator Using the Same with Leakage-Isolated Switching

(71) Applicant: PixArt Imaging Incorporation, Hsinchu (TW)

(72) Inventor: Kar-Mun Lee, Penang (MY)

(21) Appl. No.: 19/201,081

(22) Filed: May 7, 2025

(51) Int. Cl. H01C 1/16; H03K 17/687

(52) U.S. Cl. CPC H01C 1/16; H03K 17/687

(57) ABSTRACT

A trimmable resistor network is provided for generating and stabilizing a reference current. The network includes a resistor string with a plurality of unit resistors connected in series between a first and a second terminal of the resistor string. Each unit resistor is associated with a MOS switch that selectively forms a bypass path between the second end of the unit resistor and the first terminal of the resistor string. By activating specific switches, one or more resistors can be bypassed, effectively adjusting the total resistance and thereby the reference current.

### BACKGROUND OF THE INVENTION

### Field of Invention

The present invention relates to a trimmable resistor network. In particular, the invention provides a resistor trimming architecture featuring leakage-isolated switching to enhance reference current stability in advanced semiconductor processes having higher leakage current. The present invention also relates to a reference current generator using the trimmable resistor network with leakage-isolated switching.

### Description of Related Art

FIG. 1 illustrates a prior art β-Multiplier Reference Current Generator, which is based on the well-known β-MCR architecture. The reference current generator 100 comprises transistors M1 through M4 and a resistor network arranged between a pair of matched transistors (M3 and M4), wherein the gate-to-source voltage difference between M3 and M4 is used to establish a stable primary reference current I_ref through the resistor network, and thus generating a stable output reference current Iout (including Iout 5 . . . . Iout 6 and etc.) based on the primary reference current I_ref. In one embodiment, the output reference current Iout is a replica of the primary reference current I_ref, generated by a self-biased current mirror.

The resistor network includes two portions: a fixed resistor portion (R200) and a trimmable resistor portion (R100). These resistors are formed for example by unit resistors of equal size connected in series. The primary reference current I_ref is determined by the voltage drop across the combined resistor string according to Kirchhoff's Voltage Law (KVL) as the following:

VGS3=VGS4+I_ref×RT

where

RT=R100+R200, and VGS3 and VGS4 are VGS of M3 and M4 respectively, and RT is the total resistance of the fixed resistor portion R100 and the trimmable resistor portion R200.

When matched transistors M3 and M4 are configured to operate in saturation region and the number of multiplier of M4 to be K times of M3, the transconductance β4 of M4 is equal to Kβ3 (i.e., K times of the transconductance β3 of M3. Therefore, the relationship of primary reference current I_ref can be derived as:

$$I \_ ref = \frac{2}{{RT}^{2} β 3} {( 1 - \frac{1}{\sqrt{K}} )}^{2}$$

$$VTH 3 + \sqrt{\frac{2 \times I\_ref}{β 3}} = VTH 4 + \sqrt{\frac{2 \times I\_ref}{K \times β 3}} + I\_ref \times RT$$

where VTH3 and VTH4 are threshold voltages of M3 and M4 respectively.

Due to process variation (e.g., ±50% in resistance), the primary reference current I_ref, as well as the resulting output reference current Iout may deviate significantly. Therefore, R100 is made trimmable so that the resistance value can be calibrated post-fabrication, thereby stabilizing the primary reference current I_ref and the output reference current Iout.

It should be noted that the matched transistors M3 and M4 mentioned above have at least one characteristic exhibiting a non-unity multiplier relationship between them. Such characteristic may include, for example, the aforementioned transconductance ratio, current density, or physical area.

FIG. 2A shows a typical structure of the trimmable resistor portion (R100) in prior art. The trimmable resistor portion R100 includes a series connection of unit resistors, including R101, R102, . . . , R113, R114, and R115. Each unit resistor can be bypassed by a corresponding NMOS switch, such as M11, M12, . . . , M23, M24, and M25. Specifically, each NMOS switch is connected in parallel with its associated resistor: the drain terminal of the NMOS switch is coupled to the upper node of the corresponding unit resistor, and the source terminal is coupled to the lower node of that unit resistor. When a switch is turned on by applying a control voltage to its gate, it bypasses the corresponding unit resistor, reducing the total resistance of R100 and increasing I_ref.

FIG. 2B provides a tabular summary showing how different trimming codes activate corresponding switches, thereby bypassing specific resistors in R100 and modifying the total resistance. The leftmost column represents the trim code (from 0 to 15), while the second column indicates which Trim_x control signals are active. The third column counts the number of bypassed switches, and the last column shows the resulting reduction in resistance (ΔR). For example, with a trim code of 4, control signals Trim_1 through Trim_4 are activated to turn on switches M11 through M14, bypassing four unit resistors R101 to R104 and reducing R100 by 4R units.

In advanced CMOS technologies below 100 nm (e.g., 55 nm), gate-to-source leakage current becomes significant due to higher gate electric fields. In FIG. 2A, the dashed arrows indicate the intended reference current (I_ref′) flowing through the resistor string, the gray arrows indicate possible gate-to-source leakage current (I_leak1 to I_leak15), and the black arrow represents the resulting primary reference current (I_ref).

In this structure, when multiple switches are simultaneously turned on, such leakage may inadvertently flow through the resistor string, resulting in an undesired increase in I_ref. This introduces inaccuracies in current replication and degrades the performance of low-power analog circuits. The issue becomes increasingly severe as more switches are turned on, each contributing its own gate-to-source leakage current, especially under high gate-to-source voltage conditions.

FIG. 3 shows a leakage scenario in a prior art trimmable resistor network implemented in a 110 nm CMOS process. FIG. 3 illustrates the measured output reference current (Iout) remains relatively stable as the supply voltage increases from 1.9V to 3.6V. In this structure, even when multiple NMOS switches are simultaneously turned on to form bypass paths, the gate-to-source leakage current in the 110 nm process remains negligible and thus does not cause significant impact on the resistor string and the output reference current Iout. Measurement data shows that the maximum deviation ΔIout % between output reference currents at 1.9V and 3.6V is approximately 48, and this value stays consistent across trimming codes from 0 to 15, indicating that current deviation is not substantial under this process condition.

FIG. 4 shows measurement results of output reference current deviation in a 55 nm process under two different supply voltages: 1.9V and 3.6V. The two curves respectively represent the variation of Iout under each voltage condition. As the trimming code increases from 0 to 15, the deviation of Iout (ΔIout %) exhibits a significant rising trend. In particular, at the supply voltage of 3.6V, the gate voltages of all NMOS switches increase, resulting in a substantial rise in gate-to-source leakage current.

It is noteworthy that gate-to-source leakage current becomes particularly prominent when the switch is turned on, i.e., when the gate-to-source voltage exceeds the threshold level. In 55 nm or more advanced process nodes, such leakage currents can cause voltage distortion across the unit resistor, leading to deviations in the primary reference current (I_ref) and output reference current (I_out) that exceed a predetermined acceptable range. On the other hand, when the gate-to-source voltage is below the threshold level (i.e., MOS switch being off), the gate-to-source leakage current is negligible.

At trimming code 0, ΔIout % is approximately 4%. However, at trimming code 15—where all NMOS switches are turned on—and under a 3.6V supply, ΔIout % increases to about 448. This result indicates that under advanced process nodes such as 55 nm and high voltage conditions, the cumulative leakage current introduced by an increasing number of activated switches significantly interferes with the current distribution through the resistor string. Consequently, the output reference current Iout exhibits considerable deviation, highlighting the strong sensitivity of the prior art circuit to leakage effects in such conditions.

To overcome these limitations, the present invention introduces a trimmable resistor network in which only one MOS switch is activated at any time, thereby significantly reducing the impact of gate-to-source leakage current. This architectural shift, as illustrated in the following embodiments, enables accurate trimming performance even in advanced process nodes such as 55 nm, by ensuring that leakage paths do not interfere with the resistor string.

Other prior art related to this invention include US Patent: U.S. Pat. No. 8,847,572B2.

### SUMMARY OF THE INVENTION

From one perspective, the present invention provides a trimmable resistor network configured to generate a reference current. The trimmable resistor network comprises a resistor string, including a trimmable resistor portion which includes a plurality of unit resistors connected in series between a first terminal and a second terminal of the resistor string, and a plurality of MOS switches respectively associated with the plurality of unit resistors. Each unit resistor has a first end and a second end, wherein, with respect to the reference current flowing through the resistor string, the first end is electrically coupled closer to the first terminal of the resistor string than the second end. Each MOS switch has a first terminal electrically coupled to the second end of a corresponding unit resistor, and a second terminal electrically coupled to the first terminal of the resistor string. The plurality of MOS switches are configured to form bypass paths around one or more of the unit resistors, thereby adjusting an effective resistance of the resistor string, and thus adjusting the reference current.

In one preferred embodiment, the MOS switches are of a same type, being either all NMOS transistors or all PMOS transistors; and when the MOS switches are implemented as NMOS transistors, the resistor string is configured such that the reference current flows from the second terminal toward the first terminal of the resistor string, and when the MOS switches are implemented as PMOS transistors, the resistor string is configured such that the reference current flows from the first terminal toward the second terminal of the resistor string.

In one preferred embodiment, the first terminal and the second terminal of each of the MOS switches respectively correspond to a drain terminal and a source terminal of the corresponding PMOS or NMOS transistor.

In one preferred embodiment, the trimmable resistor network is configured such that gate-source leakage current from each of the MOS switches is substantially prevented from flowing through any of the unit resistors in the trimmable resistor portion of the resistor string.

In one preferred embodiment, when an absolute gate-to-source voltage of each of the MOS switches exceeds a threshold voltage to form the corresponding bypass path, the corresponding gate-source leakage current flows toward the first terminal of the resistor string and is prevented from flowing through the unit resistor within the trimmable resistor portion associated with the corresponding MOS switch.

In one preferred embodiment, when the absolute gate-to-source voltage of each of the MOS switches is below the threshold voltage, the corresponding gate-source leakage current is substantially negligible.

In one preferred embodiment, only one of the MOS switches is activated based on a trimming code associated with selection of a bypass path in the trimmable resistor portion.

In one preferred embodiment, the resistor string further includes a fixed resistor portion connected in series with the trimmable resistor portion.

In one preferred embodiment, the unit resistors have identical or different resistance values.

From another perspective, the present invention provides a reference current generator configured to generate a reference current. The reference current generator comprises the aforementioned trimmable resistor network and a pair of matched transistors, wherein one of the transistors has a characteristic that is a multiple of the other, and the multiple is greater than 1. A voltage drop across the trimmable resistor network corresponds to a gate-to-source voltage difference between the pair of matched transistors and determines the reference current.

The objectives, technical details, features, and effects of the present invention will be better understood with regard to the detailed description of the embodiments below.

### BRIEF DESCRIPTION OF THE DRAWINGS

FIG. 1 shows a typical reference current generator.

FIG. 2A shows a detailed prior art resistor-level and switch-level implementation of the trimmable resistor portion of FIG. 1, wherein each NMOS switch is connected in parallel with a corresponding unit resistor along the resistor string.

FIG. 2B illustrates a trimming table corresponding to the prior art resistor network in FIG. 2A.

FIG. 3 shows measurement results in the prior art trimmable resistor network implemented in a 110 nm CMOS process, where undesired leakage current paths through the resistor string cause insignificant deviation.

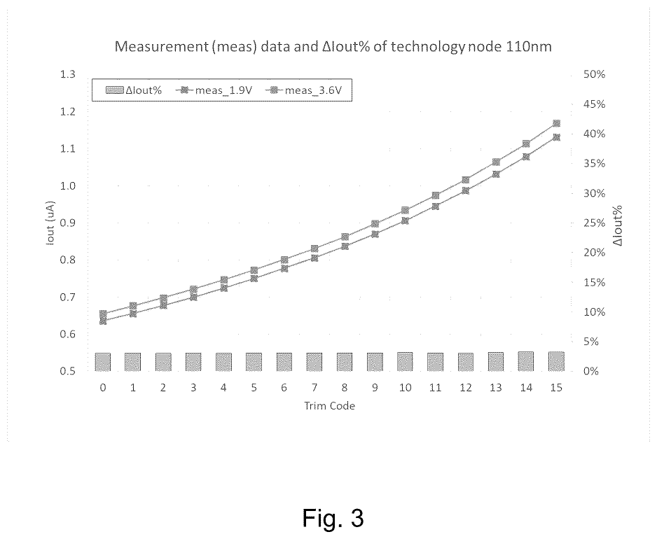

FIG. 4 shows measurement results of reference current deviation in the prior art trimmable resistor network implemented in a 55 nm CMOS process, where undesired leakage current paths through the resistor string cause significant deviation.

FIG. 5A shows a schematic diagram of an embodiment of a trimmable resistor network according to the present invention, in which each unit resistor is associated with an NMOS switch configured for single-switch activation.

FIG. 5B illustrates the trimming behavior of the proposed resistor network shown in FIG. 5A.

FIG. 6 shows comparison diagram between prior art and an embodiment of the trimmable resistor network according to the present invention, demonstrating improved reference current stability achieved using the circuit of FIG. 5 in a 55 nm process.

FIG. 7 shows an alternative embodiment of the trimmable resistor network according to the present invention, in which PMOS switches are used and configured for the same leakage isolation benefit as the NMOS-based architecture.

### DESCRIPTION OF THE PREFERRED EMBODIMENTS

The drawings as referred to throughout the description of the present invention are for illustration only, to show the interrelations between the circuits and the signal waveforms, but not drawn according to actual scale.

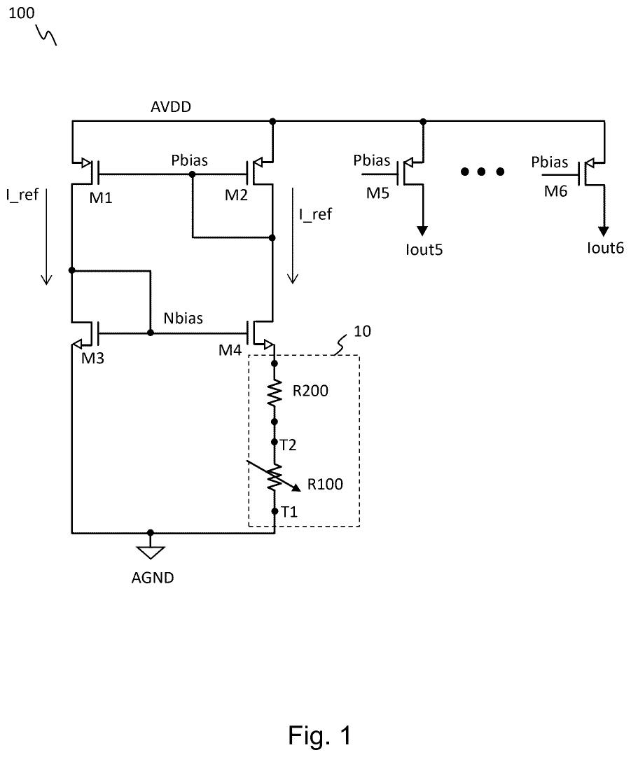

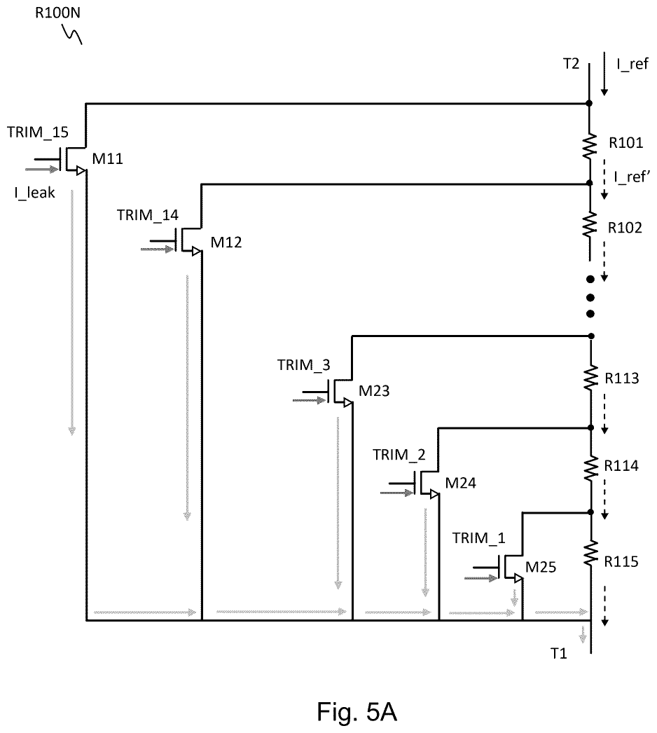

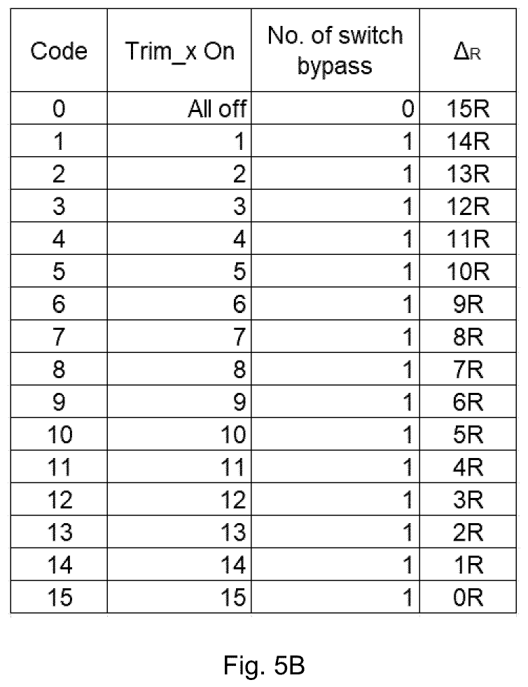

FIG. 5A illustrates the proposed trimmable resistor network architecture, in which the trimmable resistor network R100N adopts NMOS transistors (M11 to M25) as the switching elements. This trimmable resistor network can be applied to the β Multiplier Current Reference (β-MCR) architecture shown in FIG. 1, where the gate-to-source voltage difference (VGS) between a pair of matched transistors (e.g., M3 and M4) is applied across a resistor string to determine the primary reference current. The resistor string may include a fixed resistor portion and a trimmable resistor portion, with the trimmable resistor network R100N in FIG. 5 corresponding to R100 in FIG. 1. Note that, the total resistance of the resistor string remains trimmable despite inclusion of the fixed resistor portion.

As shown in FIG. 5A, the trimmable resistor portion consists of a resistor string formed by a plurality of unit resistors connected in series between a first terminal T1 and a second terminal T2. These unit resistors are labeled R101, R102, R103, . . . up to R115, and are connected sequentially from the second terminal T2 to the first terminal T1. Each unit resistor has a first end and a second end, where-according to the direction of current flow—the first and second ends respectively correspond to the ends closer to the first terminal T1 and the second terminal T2 of the resistor string. Note that these unit resistors may have identical, or different resistance values (such as having relationships of 2's power between the unit resistors).

Each trimming level corresponds to a dedicated NMOS switch, which forms a bypass path that specifically connects the second end of the selected unit resistor to the first terminal T1 of the resistor string. These MOS switches (M11 to M25) are controlled by digital signals labeled TRIM_15 down to TRIM_1. Specifically, as shown in FIG. 5, the source terminals of all the MOS switches are collectively coupled to the first terminal T1 of the resistor string, and the drain terminal of each switch is coupled to the second end of its corresponding unit resistor.

In one embodiment, only one MOS switch is activated at a time according to the applied trimming code, forming a bypass path between the second end of the selected unit resistor and the first terminal T1 of the resistor string. This configuration ensures that the gate-to-source leakage current (I_leakX, where X=1 to 15) of each MOS switch flows toward the first terminal T1 and is prevented from entering the resistor string. The structure effectively isolates gate-source leakage from the voltage drop across the unit resistors, thereby avoiding distortion in the generated reference current I_ref.

FIG. 5B provides a tabular summary illustrating the trimming behavior of the proposed trimmable resistor network shown in FIG. 5A. The table outlines how each trimming code from 0 to 15 maps to an activated switch (Trim_x), and how this impacts the number of bypassed resistors and the resulting change in resistance (ΔR).

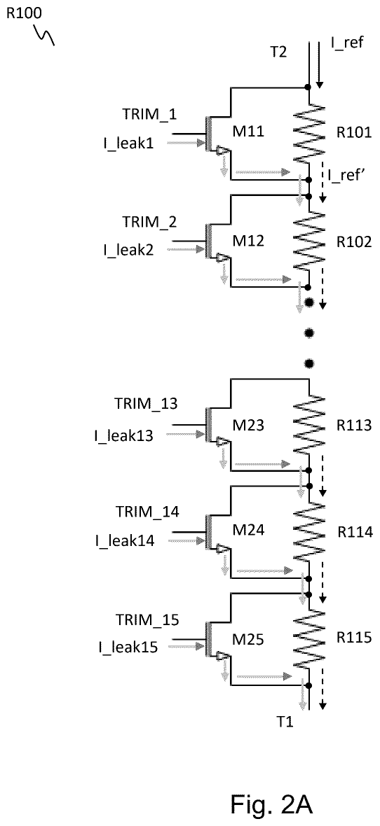

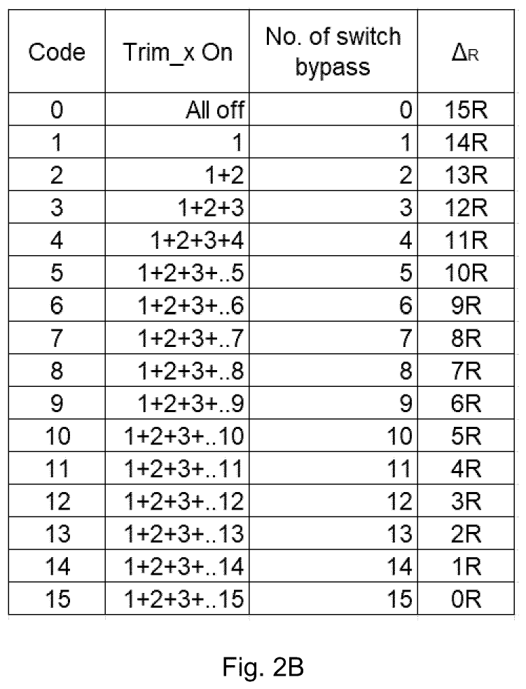

Unlike the prior art structure shown in FIG. 2B, the present design activates only one NMOS switch for each trimming code, yet is capable of bypassing one or more unit resistors simultaneously. For example, as illustrated in FIG. 5B, when the trimming code is 1, the Trim_1 signal turns on switch M25, bypassing resistor R115 and reducing the resistance by 1R; when the trimming code is 15, the Trim_15 signal turns on switch M11, bypassing R101 through R115 and reducing the total resistance by 15R.

This single-switch activation strategy effectively suppresses cumulative leakage, as only one gate-to-source conduction path is turned on in any trimming state. This improves the accuracy of the reference current and reduces sensitivity to gate-to-source leakage effects.

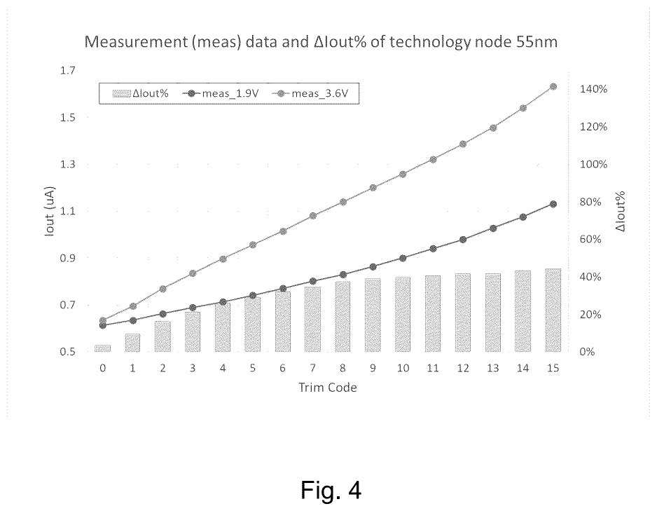

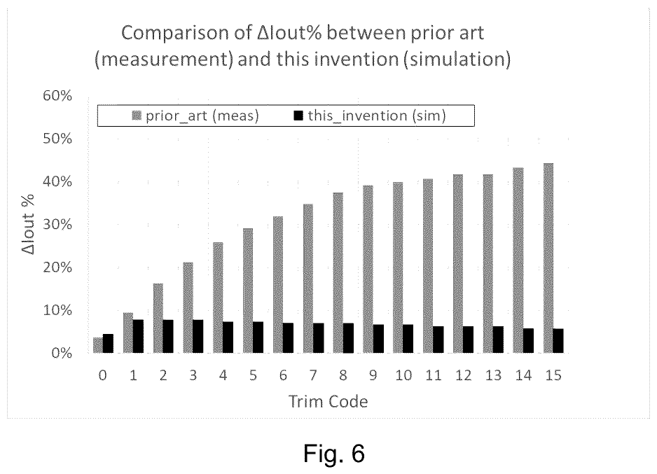

FIG. 6 illustrates simulation results conducted in a 55 nm process using the proposed architecture, demonstrating a significant reduction in the deviation (ΔIout %) of the output reference current. Compared to the prior art structure shown in FIG. 4—where the deviation ΔIout % under the same process and supply voltage conditions (1.9V and 3.6V) reaches as high as 44% (also annotated in FIG. 6)—the proposed trimmable resistor network suppresses the deviation to below 8% and maintains consistent performance. This result indicates that the design strategy of activating only a single switch and routing all leakage currents toward a common terminal effectively achieves gate-to-source leakage isolation, ensuring stable reference current output even under advanced process and high-voltage conditions.

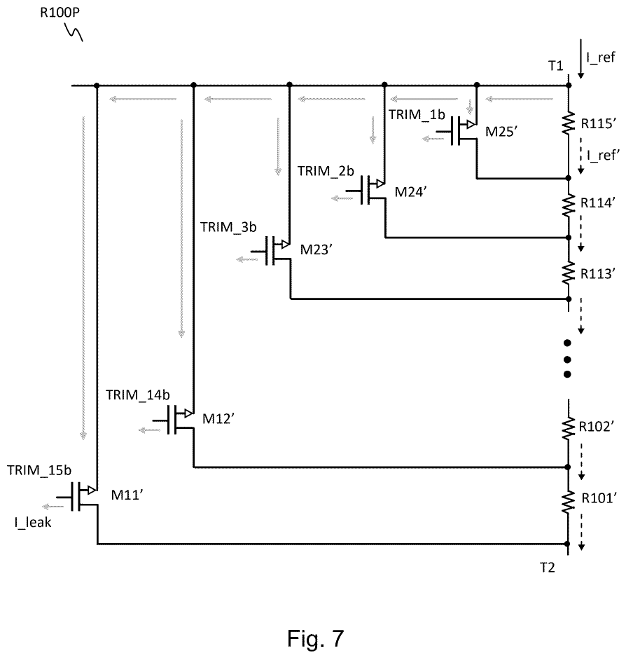

FIG. 7 illustrates another embodiment of the present invention, in which the trimmable resistor network R100P shares a similar architecture with that shown in FIG. 5A. The primary difference lies in replacing the NMOS switching elements (M11 to M25) with PMOS transistors (denoted M11′ to M25′), and employing complementary control signals (Trim_15b to Trim_1b) to achieve the same trimming and leakage isolation objectives.

In this embodiment, the unit resistors (R101′ to R115′) are still connected in series from the second terminal T2 to the first terminal T1. Each unit resistor has a first and second end, respectively located near T1 and T2 according to the current flow direction. Similar to the NMOS-based implementation in FIG. 5A, the source terminals of the PMOS switches are commonly coupled to the first terminal T1, while the drain terminals are connected to the second end of their corresponding unit resistors (i.e., the end closer to T2), thereby preserving the intended current direction and maintaining the leakage isolation design.

In this PMOS version, only one switch is activated for each trimming code, forming a bypass path from the second end of a selected unit resistor to the first terminal T1 of the resistor string. As a result, the gate-to-source leakage current from each PMOS switch is directed from a common node (T1) toward its respective gate. This structure achieves the same leakage isolation effect as FIG. 5A, suppressing deviations in the output reference current and improving robustness against leakage effects under advanced process and high-voltage conditions.

In summary, the proposed trimming resistor network architecture addresses a critical challenge in advanced semiconductor technologies-namely, the gate-to-source leakage-induced distortion in reference current generator circuits. By ensuring single-switch activation and strategic source coupling, the design achieves superior leakage isolation, maintains trimming accuracy across a wide range of trimming codes, and proves robust under process variation. These advantages make it well-suited for integration into precision analog circuits requiring stable reference currents.

The present invention has been described in considerable detail with reference to certain preferred embodiments thereof. It should be understood that the description is for illustrative purpose, not for limiting the scope of the present invention. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. Furthermore, those skilled in this art can readily conceive variations and modifications within the spirit of the present invention. For example, to perform an action “according to” a certain signal as described in the context of the present invention is not limited to performing an action strictly according to the signal itself, but can be performing an action according to a converted form or a scaled-up or down form of the signal, i.e., the signal can be processed by a voltage-to-current conversion, a current-to-voltage conversion, and/or a ratio conversion, etc. before an action is performed. The spirit of the present invention should cover all such and other modifications and variations, which should be interpreted to fall within the scope of the following claims and their equivalents.

What is claimed is:

1. A trimmable resistor network configured to generate a reference current, comprising:
a resistor string, including a trimmable resistor portion which includes a plurality of unit resistors connected in series between a first terminal and a second terminal of the resistor string; and
a plurality of MOS switches respectively associated with the plurality of unit resistors;
wherein:
each unit resistor has a first end and a second end, wherein, with respect to the reference current flowing through the resistor string, the first end is electrically coupled closer to the first terminal of the resistor string than the second end;
each MOS switch has a first terminal coupled to the second end of a corresponding unit resistor, and a second terminal coupled to the first terminal of the resistor string; and
wherein the plurality of MOS switches are configured to form bypass paths around one or more of the unit resistors, thereby adjusting an effective resistance of the resistor string, and thus adjusting the reference current.

2. The trimmable resistor network of claim 1,
wherein the MOS switches are of a same type, being either all NMOS transistors or all PMOS transistors;
and wherein:
when the MOS switches are implemented as NMOS transistors, the resistor string is configured such that the reference current flows from the second terminal toward the first terminal of the resistor string, and when the MOS switches are implemented as PMOS transistors, the resistor string is configured such that the reference current flows from the first terminal toward the second terminal of the resistor string.

3. The trimmable resistor network of claim 2,
wherein the first terminal and the second terminal of each of the MOS switches respectively correspond to a drain terminal and a source terminal of the corresponding PMOS or NMOS transistor.

4. The trimmable resistor network of claim 1,
wherein the trimmable resistor network is configured such that gate-source leakage current from each of the MOS switches is substantially prevented from flowing through any of the unit resistors in the trimmable resistor portion of the resistor string.

5. The trimmable resistor network of claim 4,
wherein when an absolute gate-to-source voltage of each of the MOS switches exceeds a threshold voltage to form the corresponding bypass path, the corresponding gate-source leakage current flows toward the first terminal of the resistor string and is prevented from flowing through the unit resistor within the trimmable resistor portion associated with the corresponding MOS switch.

6. The trimmable resistor network of claim 4,
wherein when the absolute gate-to-source voltage of each of the MOS switches is below the threshold voltage, the corresponding gate-source leakage current is substantially negligible.

7. The trimmable resistor network of claim 1,
wherein only one of the MOS switches is activated based on a trimming code associated with selection of a bypass path in the trimmable resistor portion.

8. The trimmable resistor network of claim 1,
wherein the resistor string further includes a fixed resistor portion connected in series with the trimmable resistor portion.

9. The trimmable resistor network of claim 1, the unit resistors have identical or different resistance values.

10. A reference current generator configured to generate a reference current, comprising:
the trimmable resistor network of claim 1, and
a pair of matched transistors, wherein one of the transistors has a characteristic that is a multiple of the other, and the multiple is greater than 1;
wherein a voltage drop across the trimmable resistor network corresponds to a gate-to-source voltage difference between the pair of matched transistors and determines the reference current.
